(19) United States
(12) Patent Application Publication
(10) Pub. No.: US 2007/0099386 A1
(43) Pub. Date: May 3, 2007

(54) INTEGRATION SCHEME FOR HIGH GAIN FET IN STANDARD CMOS PROCESS

(75) Inventors: Douglas D. Coolbaugh, Essex Junction, VT (US); Ebenezer E. Eshun, Essex Junction, VT (US); Robert M. Rassel, Colchester, VT (US); James A. Slinkman, Montpelier, VT (US); Michael J. Zierak, Essex Junction, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 11/163,791

(22) Filed: Oct. 31, 2005

(51) Int. Cl. H01L 21/336; H01L 29/788

(52) U.S. Cl. 438/286; 257/315

(57) ABSTRACT

A method for fabricating high gain FETs that substantially reduces or eliminates unwanted variation in device characteristics caused by using a prior art shadow masking process is provided. The inventive method employs a blocking mask that at least partially extends over the gate region wherein after extension and halo implants an FET having an asymmetric halo region asymmetric extension regions or a combination thereof is fabricated. The inventive method thus provides high gain FETs in which the variation of device characteristics is substantially reduced. The present invention also relates to the resulting asymmetric high gain FET device that is fabricated utilizing the method of the present invention.

### FIELD OF THE INVENTION

The present invention relates to semiconductor device manufacturing, and more particularly to a method of forming a high gain field effect transistor (FET) device, which includes an asymmetric halo region, an asymmetric extension region or a combination thereof to increase the self-gain of the device. The term “self gain” is defined as gm/gds, wherein gm=transconductance, and gds=drain conductance). The present invention also relates to the high gain FET device that is fabricated utilizing the method of the present invention. In accordance with the present invention, the high gain FET device includes at least one of an asymmetric halo region or an asymmetric extension region.

### BACKGROUND OF THE INVENTION

In complementary metal oxide semiconductor (CMOS) technologies, there is a need for high gain field effect transistors (FETs) for high performance analog circuits. This is because as transistor scaling continues to smaller gate lengths, the halo or pocket implant doses increase resulting in lower transistor self-gain. A key figure of merit for analog applications is the transistor self-gain requiring special devices with high self-gain integrated as part of the CMOS process. The term “high gain FET” is typically used to denote a FET that is characterized as having a source region including extension and halo implants and a drain region including an extension implant, without a halo implant or with a reduced halo implant. Another name for a high gain FET is an asymmetric drain field effect transistor (ADFET).

The prior art integration technique for fabricating high gain FETs is complex and critically depends on numerous manufacturing processes. Specifically, the prior art integration technique implants unique extension and halo implants for fabricating high gain FETs utilizing one additional mask by shadowing the halo implant from the drain side of the FET structure. This prior art technique, which is referred as a shadow mask technique, uses a thick block mask to block angled halo implants from entering into the drain region. This technique is depicted in FIGS. 1A-1B of the present application. Specifically, FIG. 1A shows a structure during an extension implant step 20 in which block mask 18 is present on a surface of a semiconductor substrate 10 and is adjacent to a patterned gate region 16; the patterned gate region 16 includes gate dielectric 12 and gate conductor 14. Particularly, the block mask 18 is formed on the drain side of the FET utilizing conventional processing steps well known in the art including block mask deposition, lithography and optionally etching. In the drawings that accompany the present application, the source side of the FET is labeled as “S” and the drain side is labeled as “D”. In this step of the prior art process, the extension implant 20 is allowed to go into the source and drain regions of the FET forming extension regions 22 in both the S and D sides.

FIG. 1B shows the same structure during an angled halo implantation step 24. As shown, the halo implant 24 is at a specific angle, which prevents most of the halo ions from being implanted into the drain side of the FET. Instead, a halo region 26 is formed only in the source side of the FET.

It is noted that the block mask 18 is set at a very specific distance relative to the patterned gate region 16 and its thickness is also set as a specific value to correlate to the halo ion implantation angle. One advantage of utilizing the prior art technique illustrated in FIGS. 1A-1B is that it allows all gate conductor lengths, including technology minimum lengths. The disadvantages of the prior art technique are numerous and include, for example, critical process dimensions for block mask thickness and, proper block mask to gate conductor spacing for manufacturing a critical dimension. Also, overlay tolerances are critical to the device to ensure halo blocking consistency. Variation in critical dimension and overlay for block mask thickness and block mask distance will result in variations in the resultant device.

In view of the above, there is a need for providing another integration scheme for fabricating high gain FETs that substantially reduces or eliminates the unwanted variation in device characteristics caused by using the prior art shadow masking process mentioned above.

### SUMMARY OF THE INVENTION

The present invention provides a method for fabricating high gain FETs that substantially reduces or eliminates unwanted variation in device characteristics caused by using the prior art shadow masking process mentioned above. This invention employs a blocking mask that at least partially extends over the gate region wherein after extension implants and an optional halo implant a FET having an asymmetric halo region, an asymmetric extension region or a combination thereof is fabricated. The inventive method thus provides high gain FETs in which the variation of device characteristics is substantially reduced or even eliminated. The present invention also relates to the resulting asymmetric high gain FET device that is fabricated utilizing the method of the present invention.

In general terms, the method of the present invention comprises the steps of:

providing a structure including at least one patterned gate region located on a surface of a semiconductor substrate, said at least one patterned gate region including a source side and a drain side;

forming a first block mask on said drain side of said at least one patterned gate region, said first block mask at least partially extends over the at least one patterned gate region;

performing a first extension implant to form a first extension region in said source side, wherein said first block mask prevents formation of said first extension region in said drain side;

removing said first block mask; and

performing a second extension implant at least within said drain side of the patterned gate region forming a second extension region at least with said drain side that has a different profile than the first extension region.

By “different profile” it is meant that the second extension region typically has a different junction depth and/or dopant concentration than the first extension region.

In one embodiment of the present invention, a halo region can be formed into the source side of the structure. When this embodiment is employed, a halo implant is performed with the first block mask in place. The halo implantation may be performed prior to, or preferably, after the first extension implant.

In another embodiment, a second block mask is formed on the source side of the at least one patterned gate region prior to performing the second extension implant. When this embodiment is employed, the second block mask at least partially extends over the at least one patterned gate region. The presence of the second block mask prevents the second extension region from being formed into the source side of the structure.

In yet another embodiment of the present invention, no second block mask is present on the source side during the second extension implant. Since no second block mask is used in such an embodiment, the second extension region is formed into both the source and drain sides of the structure.

The present invention also relates to a semiconductor structure that is formed utilizing the method of the present invention. In general terms, the semiconductor structure of the present invention comprises:

at least one patterned gate region located on a surface of a semiconductor substrate, said at least one patterned gate region including a source side and a drain side; and

a first extension region located in the source side and a second extension region located in the drain side, wherein said second extension region has a different profile than the first extension region.

The term “different profile” is used herein to denote that the first and second extension regions could have a different depth, a different concentration or a combination thereof.

In some embodiments of the present invention, the second extension region can also be located in the source side of the structure. In yet other embodiments, a halo region can be located in the source side of the structure. It is noted that when a halo region is present, it can be present with, or without, the second extension region present in the source side of the structure.

It is noted that the present invention thus provides a semiconductor structure including an asymmetric halo region, an asymmetric extension region or a combination thereof. The asymmetric extension region can broadly include the extension regions of different profiles wherein one extension region is formed on the source side and the other is formed on the drain side. Alternatively, the asymmetric extension region may include the first and the second extension region on the source side and the second extension region on the drain side.

### BRIEF DESCRIPTION OF THE DRAWINGS OF THE INVENTION

FIGS. 1A-1B are pictorial representations (through cross sectional views) depicting the prior art process for fabricating high gain FETs.

FIGS. 2A-2D are pictorial representations (through cross sectional views) depicting basic processing steps of the present invention for fabricating high gain FETs.

### DETAILED DESCRIPTION OF THE INVENTION

The present invention, which provides a method for fabricating a high gain FET and the resultant high gain FET device fabricated by the inventive method, will now be described in greater detail by referring to the following discussion and drawings that accompany the present application. It is noted that the drawings of the present invention are provided for illustrative purposes and, as such, they are not drawn to scale.

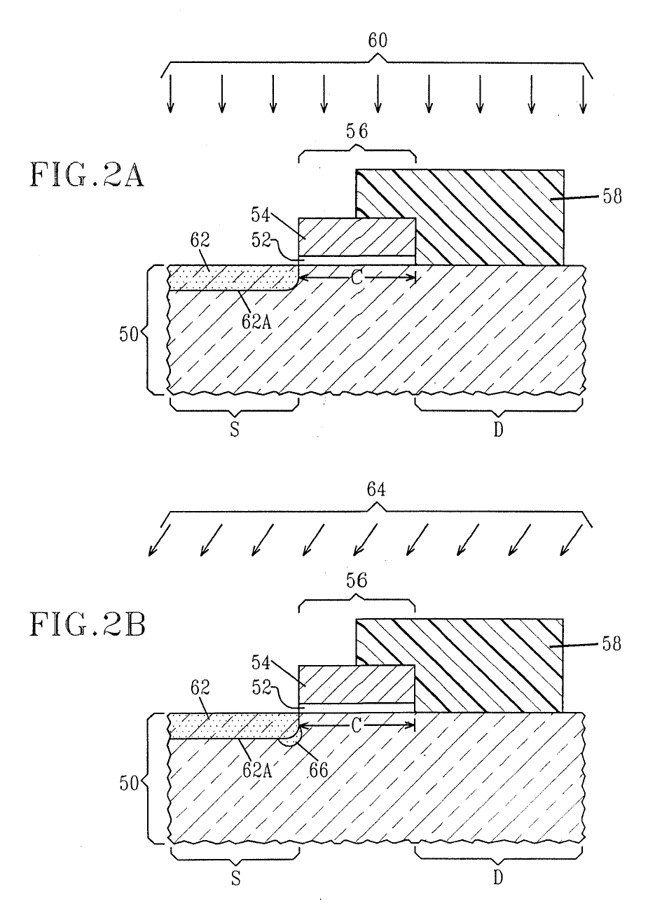

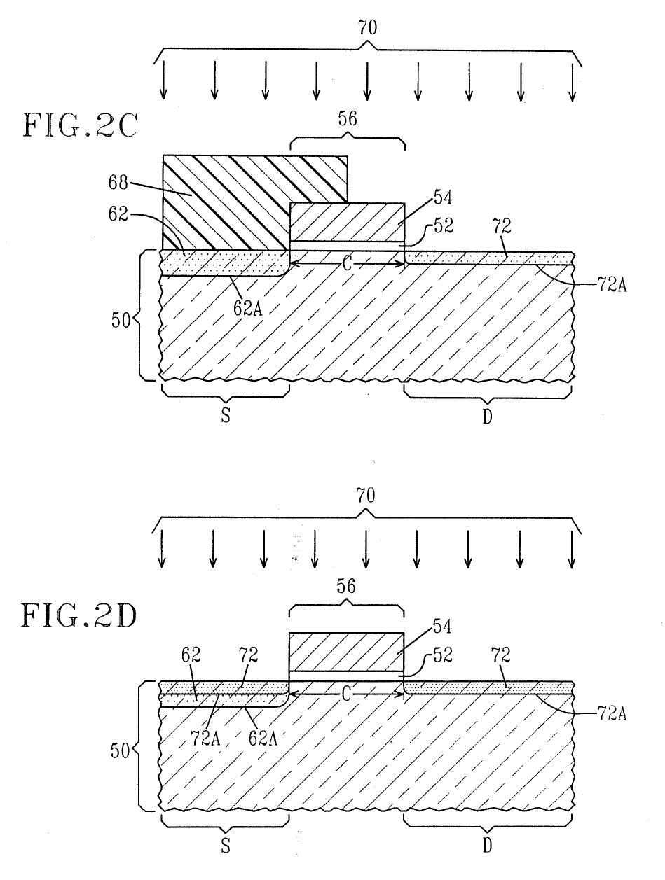

Reference is made to FIGS. 2A-2D which illustrate the basic processing steps of the present invention. The method of the present invention begins with first providing a patterned gate stack 56 on a surface of a semiconductor substrate 50. The at least one patterned gate stack 56 includes a gate dielectric 52 and an overlying gate conductor 54. The at least one patterned gate stack 56 may be an n-FET or a p-FET. The present invention also contemplates a plurality of patterned gate stacks on the surface of the semiconductor substrate which may all be n-FETs, all p-FETs or a combination thereof.

The at least one patterned gate stack 56 may be formed utilizing conventional deposition, lithography and etching or a conventional gate replacement process can be used in forming the same. It is emphasized that the processing steps of forming the at least one patterned gate stack 56 are well known in the art and, as such, details concerning the fabrication of the at least one gate stack 56 are not provided herein. The at least one patterned gate stack 56 may optionally include at least one gate spacer (not shown) located on the sidewalls of the patterned gate stack 56. The at least one gate spacer may comprise any insulating material including, for example, an oxide, a nitride, an oxynitride or any combination thereof. The at least one gate spacer is formed utilizing conventional techniques well known in the art. Alternatively, the sidewalls of at least the gate conductor may include a passivation layer formed thereon utilizing conventional processing techniques well known in the art.

The semiconductor substrate 50 employed in the present invention comprises any semiconducting material including, but not limited to: Si, Ge, SiGe, SiC, SiGeC, Ga, GaAs, InAs, InP and all other III/V or II/VI compound semiconductors. The semiconductor substrate 50 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 50 be composed of a Si-containing semiconductor material, i.e., a semiconductor material that includes silicon. The semiconductor substrate 50 may be doped, undoped or contain doped and undoped regions therein.

At least one isolation region (not shown) is typically present within the semiconductor substrate 50 to provide isolation between devices of different conductivity. The isolation region may be a trench isolation region or a field oxide isolation region which are both formed utilizing techniques well known in the art.

The gate dielectric 52 is comprised of an insulating material having a dielectric constant of about 4.0 or greater, preferably greater than 7.0. The dielectric constants mentioned herein are relative to a vacuum, unless otherwise stated. Note that SiO₂ typically has a dielectric constant that is about 4.0. Specifically, the gate dielectric 52 employed in the present invention includes, but is not limited to: an oxide, nitride, oxynitride and/or silicates including metal silicates, aluminates, titanates and nitrides. In one embodiment, it is preferred that the gate dielectric 52 is comprised of an oxide such as, for example, SiO₂, HfO₂, ZrO₂, Al₂O₃, TiO₂, La₂O₃, SrTiO₃, LaAlO₃, Y₂O₃ and mixtures thereof.

The physical thickness of the gate dielectric 52 may vary, but typically, the gate dielectric has a thickness from about 0.5 to about 10 nm, with a thickness from about 0.5 to about 3 nm being more typical.

The gate conductor 54 may comprise polysilicon, SiGe, a silicide, a metal, a metal-silicon-nitride such as Ta—Si—N or any other conductive material. Examples of metals that can be used as the gate conductor 54 include, but are not limited to: Al, W, Cu, Ti or other like conductive metals. The thickness, i.e., height, of the gate conductor 54 may vary depending on the technique used in forming the same. Typically, the gate conductor 54 has a vertical thickness from about 20 to about 180 nm, with a thickness from about 40 to about 150 nm being more typical.

It is noted that each of the patterned gate stacks 56 includes a source side, S, and a drain side, D. The source side defines the area where the source diffusion region will be subsequently formed, while the drain side defines the area in which the drain diffusion region will be subsequently formed. The source and drain sides are located on adjacent sides of each patterned gate stacks and the area located beneath each patterned gate stack is referred to as the channel, C.

The structure shown in FIG. 2A also includes a first block mask 58 on the drain side of the at least one patterned gate region 56. In accordance with the present invention, the first block mask 58 at least partially extends over the at least one patterned gate region 56. The first block mask 58 is comprised of any material such as a photoresist and/or an insulating material, that can prevent various implants from entering into the semiconductor substrate 50. The first block mask 58 is formed by deposition, lithography and optionally etching. The thickness of the first block mask 58 may vary depending on the material used. Typically, the first block mask 58 has a thickness that is greater than that of the patterned gate stack 56. Illustratively, the first block mask 58 has a thickness from about 200 to about 800 nm.

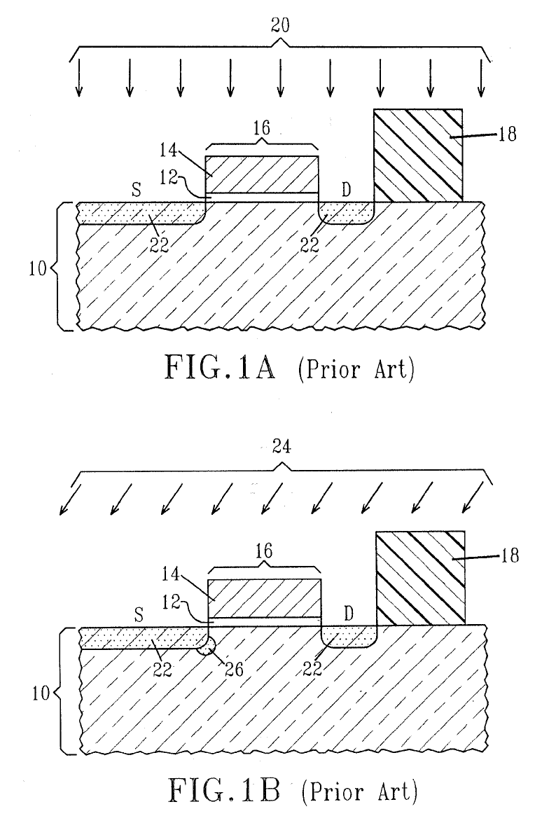

It is noted that the position of the first block mask 58 is different from that used in the prior art process. As stated above, the first block mask 58 employed in the present invention at least partially extends over a top surface of the at least one patterned gate region 56. In the prior art process, the block mask is formed in the drain side at a predetermined distance from the patterned gate stack, as is shown, for example, in FIG. 1A. Because of the position of the block mask used in the present invention relative to the patterned gate region, variation in block mask thickness, overlay and image tolerance will not affect the device characteristics.

FIG. 2A also shown the structure during a first extension implant 60 which forms a first extension region 62 in the source side of the structure; note that because of the presence of the first block mask 58, the first extension region 62 is not formed into the drain side of the structure. The first extension implant 60 comprises the use of a first conductivity type dopant (n- or p-type). The implant 60 is performed utilizing standard conditions well known in the art, which conditions may vary depending upon the dopant type being implanted. Reference numeral 62A denotes the junction depth of the first extension region 62.

For example, and for n-type dopants, the extension implant 60 is performed at an energy from about 1 to about 5 keV, with an energy from about 2 to about 3 keV being even more typical. The n-type dopant dosage used in this implant 60 is typically from about 1e15 to about 5e15 atoms/cm⁻², with an n-type dopant dosage from about 2e15 to about 4e15 atoms/cm⁻² being more typical.

When p-type dopants are used in this implant, the extension implant 60 is performed at an energy from about 2 to about 6 keV, with an energy from about 4 to about 5 keV being even more typical. The p-type dopant dosage is typically from about 1e15 to about 5e15 atoms/cm⁻², with a p-type dopant dosage from about 2e15 to about 4e15 atoms/cm⁻² being more typical.

FIG. 2B illustrates the structure of FIG. 2A during an optional halo implant 64 which forms halo region 66 within the source side only. The optional halo implant 64 is performed utilizing a conventional halo ion and conditions that are well known in the art can be employed. The halo implant is typically performed at an angle relative to the substrate surface in order to place the implants under the gate where the implant angle is from about 10° to about 45°. Typically, the optional halo implant 64 is performed at an energy from about 5 to about 100 keV, with an energy from about 10 to about 80 keV being even more typical. The halo dosage is typically from about 1e13 to about 9e13 atoms/cm⁻².

Next, the first block mask 58 is removed from the structure utilizing a conventional stripping process well known in the art. In one particular embodiment shown in FIG. 2C, a second block mask 68 is formed on the source side of the at least one patterned gate region 56. In accordance with the present invention, the second block mask 68 at least partially extends over the at least one patterned gate region 56. The second block mask 68 is comprised of any material such as a photoresist and/or an insulating material, that can prevent various implants from entering into the semiconductor substrate 50. The second block mask 68 is formed by deposition, lithography and optionally etching. The thickness of the second block mask 68 may vary depending on the material used. Typically, the second block mask 68 has a thickness that is greater than that of the patterned gate stack 56. Illustratively, the second block mask 68 has a thickness from about 200 to about 800 nm.

It is noted that the presence of the second block mask 68 on the source side prevents a second extension region 72 from being formed in the source side of the structure. This step of the present invention is shown in FIG. 2C. FIG. 2D shows an embodiment of the present invention in which no second block mask 68 is employed. In this embodiment in which the second block mask 68 is not employed, the second extension region 72 is formed in both the drain and source sides of the structure. Note that in both FIGS. 2C and 2D the optional halo region is not shown. Although the optional halo region is not shown, the present invention contemplates halo implants in both of these structures.

In both FIGS. 2C and 2D, the second extension implant is labeled as 70 and the second extension region is labeled as 72. The second extension implant 70 comprises the use of the first conductivity type dopant (n- or p-type). The implant 70 is performed utilizing standard conditions which form a second extension region 72 within at least the drain side of the structure that typically has a different profile, i.e., junction depth and/or concentration than that of the first extension implant 60. The different profile may manifest a deeper or shallower junction depth than the first extension region 60, and/or a larger or smaller dopant concentration than that of the first extension implant. In the drawings, the second extension region 72 is shown as having a shallower junction depth 72A than the first extension region 62. This illustration is for example only.

It is noted that the conditions for the second extension implant 70 can be adjusted from those used in the first extension implant 60 to provide the desired change in the profile of the second extension region 72 as compared to the first extension region 62. The manipulation of these conditions is within the knowledge of a skilled artisan.

If a second block mask is employed, the second block mask 68 can be stripped after the implant process utilizing techniques well known in the art. Following the second extension implant 70, conventional CMOS processing including spacer formation, source/drain diffusion region formation, silicidation, and interconnect formation may be performed.

Depending on the processing steps employed, the method of the present invention can form a structure having a first extension region in the source side and a second extension region in the drain side wherein the second extension region may have a different profile than the first extension region. The method of the present invention is also capable of providing structures having an asymmetric halo region, an asymmetric extension region or a combination thereof. The asymmetry is typically provided in the source side of the structure.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

1. A method of fabricating a semiconductor structure comprising:
providing at least one field effect transistor structure including a patterned gate region located on a surface of a semiconductor substrate, said patterned gate region including a source side and a drain side;
forming a first block mask on said drain side of said patterned gate region, said first block mask at least partially extends over the patterned gate region;
performing a first extension implant to form a first extension region in said source side, wherein said first block mask prevents formation of said first extension region in said drain side;
removing said first block mask; and
performing a second extension implant utilizing a second block mask forming a second extension region within said drain side having a different profile than the first extension region.

2. The method of claim 1 wherein said different profile comprises a different junction depth, a different dopant concentration or a combination thereof.

3. The method of claim 1 further comprising forming a halo region in said source side, said halo region is formed with said first block mask in place.

4. The method of claim 3 wherein said halo region is formed prior to performing said first extension implant.

5. The method of claim 3 wherein said halo region is formed after performing said first extension implant.

6. The method of claim 3 wherein said halo region is formed by a halo implantation process that is performed at an angle relative to the surface of said semiconductor substrate, said angle is from about 10° to about 45°.

7. The method of claim 1 wherein said first extension implant comprises implanting a p-type dopant or an n-type dopant.

8-9. (canceled)

10. The method of claim 1 wherein said patterned gate region comprises a gate dielectric and a gate conductor which are located on the surface of said semiconductor substrate.

11. The method of claim 1 further comprising forming a halo region in said source side, said halo region is formed with said first block mask in place, and further comprising forming said second block mask on said source side that partially extends over the patterned gate stack, and said forming said second block mask is performed between said removing of said first block mask and said performing said second extension implant.

12. (canceled)

13. A method of fabricating a semiconductor structure comprising:
providing at least one field effect transistor structure including a patterned gate region located on a surface of a semiconductor substrate, said patterned gate region including a source side and a drain side;
forming a first block mask on said drain side of said patterned gate region, said first block mask at least partially extends over the patterned gate region;
performing a first extension implant and a halo implant, in any order, to form a first extension region and a halo region in said source side, wherein said first block mask prevents formation of said first extension region and said halo region in said drain side;
removing said first block mask; and
performing a second extension implant at least within said drain side of the patterned gate region to form a second extension region in at least the drain side having a different profile than the first extension region.

14. The method of claim 13 wherein said different profile comprises a different junction depth, a different dopant concentration or a combination thereof.

15. The method of claim 13 further comprising forming a second block mask on said source side that partially extends over the patterned gate stack, and said forming said second block mask is performed between said removing of said first block mask and said performing said second extension implant.

16. The method of claim 13 wherein said second extension implant is performed without the use of a block mask such that said second extension region also forms in said source side.

17. A semiconductor structure comprising:
at least one field effect transistor including a patterned gate region located on a surface of a semiconductor substrate, said patterned gate region including a source side and a drain side;
a first extension region located in the source side and a second extension region located in the drain side, wherein said second extension region has a different profile than the first extension region; and
a halo region in said source side in contact with said first extension region.

18. The semiconductor structure of claim 17 wherein said different profile comprises a different junction depth, a different dopant concentration or a combination thereof.

19. (canceled)

20. The semiconductor structure of claim 17 further comprising said second extension region in said source side.

21. (canceled)

22. The semiconductor structure of claim 17 wherein said patterned gate region comprises a gate dielectric and a gate conductor located on said surface of the semiconductor substrate.

23. The semiconductor structure of claim 17 wherein said semiconductor substrate is a Si-containing semiconductor material.

24. A semiconductor structure comprising:
at least one field effect transistor including a patterned gate region located on a surface of a semiconductor substrate, said patterned gate region including a source side and a drain side; and
a first extension region and a halo region located in the source side and a second extension region located in the drain side, wherein said second extension region has a different profile than the first extension region and said halo region is not located in said drain side.

25. The semiconductor structure of claim 24 wherein said different profile comprises a different junction depth, a different dopant concentration or a combination thereof.

26. The semiconductor structure of claim 24 further comprising said second extension region in said source.

27. The semiconductor structure of claim 24 wherein said patterned gate region comprises a gate dielectric and a gate conductor located on said surface of the semiconductor substrate.

28. The semiconductor structure of claim 24 wherein said semiconductor substrate is a Si-containing semiconductor material.
